(19) United States
(12) Patent Application Publication
(10) Pub. No.: US 2009/0057713 A1
(43) Pub. Date: Mar. 5, 2009

(54) SEMICONDUCTOR DEVICE WITH A SEMICONDUCTOR BODY

(75) Inventor: Franz Hirler, Isen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies Austria AG, Villach (AT)

(21) Appl. No.: 11/848,776

(22) Filed: Aug. 31, 2007

(51) Int. Cl. H01L 29/739; H01L 21/336; H01L 29/78

(52) U.S. Cl. 257/143; 257/330; 257/339; 438/270; 257/E29.201; 257/E21.41; 257/E29.256; 257/E29.26

(57) ABSTRACT

A semiconductor body includes a drift zone of a first conduction type. A body zone of a second conduction type complementary to the first conduction type is located near the surface in the semiconductor body. The semiconductor body includes a near-surface field stop zone of the second complementary conduction type and doped more lightly than the body zone.

### BACKGROUND

The present disclosure relates to a semiconductor device with a semiconductor body. Such semiconductor devices include DMOS-transistors with or without charge compensation zones in the drift zone. Such charge compensation zones include depletable p-type columns or depletable or floating non-depletable p-type regions in the drift zone. This type of charge carrier compensation can be matched very precisely to the breakdown charge of the relevant semiconductor material.

Such semiconductor devices are moreover characterized by a constant or only slightly varying doping over the depth or length of the drift zone. If, in such precise compensation with constant doping, the compensation is changed by a current flow of a few amperes in an avalanche situation, such semiconductor devices cannot take up any additional voltage. As a result, the breakdown characteristic snaps back even at low currents. This snapping back of the breakdown characteristic can result in the destruction of the device.

This does not only happen in DMOS-transistors, but also in IGBT-type (insulated gate polar transistor) power diodes or transistors with a very low and homogeneous basic doping of the drift section.

The snapping back of the breakdown characteristic can be limited by variable doping of the columns in charge compensation devices such as “CoolMOS”-type DMOS-transistors. This variable doping of the columns has the disadvantage that it makes production difficult. In particular, it is virtually impossible to apply it to semiconductor devices with trench structure concepts. These difficulties are increased even more in the case of semiconductor devices wherein complementary doping of drift zones and charge compensation zones has to be introduced through the trench walls.

To improve the avalanche resistance of these semiconductor devices, it is possible to place a field stop of the same conduction type as the drift zone in the lower region of the charge compensation columns. This field stop region is located in the lower region of the drift zones between the charge compensation columns. For this purpose, for example, an n-type zone with a slightly higher doping than the drift zone is introduced between the p-type charge compensation zones in the lower regions of the drift zones of a DMOS. In a case of reverse bias, the field stop zone cannot be depleted completely, i.e. the field stop zone sets a lower limit for the expansion of the space-charge zone in a vertical semiconductor device of this type. If, with an increasing current density of a few amperes in an avalanche situation, the movable charge carriers compensate the background charge, the space-charge zone can only spread into the field stop zone, enabling the semiconductor device to take up a higher voltage.

This means that the breakdown characteristic only snaps back at higher currents. The field stop zone located in the lower region of a DMOS-transistor therefore prevents the premature destruction of the semiconductor device by the snapping back of the breakdown characteristic in an avalanche situation. A field stop zone of a conduction type complementary to the drift zone, if installed in the lower region of vertically structured semiconductor devices, can therefore shift the snapping back of the breakdown characteristic to higher currents in high-voltage diodes or IGBT-type transistors with a very low basic doping of the drift section, thereby improving the electric strength of such semiconductor devices in an avalanche situation.

For these and other reasons, there is a need for the present invention.

### SUMMARY

An embodiment includes a semiconductor device, such as an integrated circuit, with a semiconductor body. The semiconductor body has a drift zone of a first conduction type. In addition, the semiconductor body includes a near-surface field stop zone with a second complementary conduction type and a lighter doping than the body zone, so that the field stop zone takes up voltage only when a defined blocking current density is exceeded.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagrammatic cross-section through a semiconductor device according to an embodiment.

FIG. 2 is a diagram comparing the breakdown characteristics of semiconductor devices with and without a field stop zone.

FIG. 3 is a diagrammatic representation of an enlarged region of the diagram according to FIG. 2.

FIG. 4 is a diagrammatic cross-section through another semiconductor device according to an embodiment.

FIG. 5 is a diagrammatic cross-section through a further semiconductor device according to an embodiment.

FIG. 6 is a diagrammatic representation of the doping material profiles of semiconductor devices with and without a field stop zone.

FIG. 7 is a diagrammatic cross-section through a semiconductor device with an epitaxially produced charge compensation structure.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

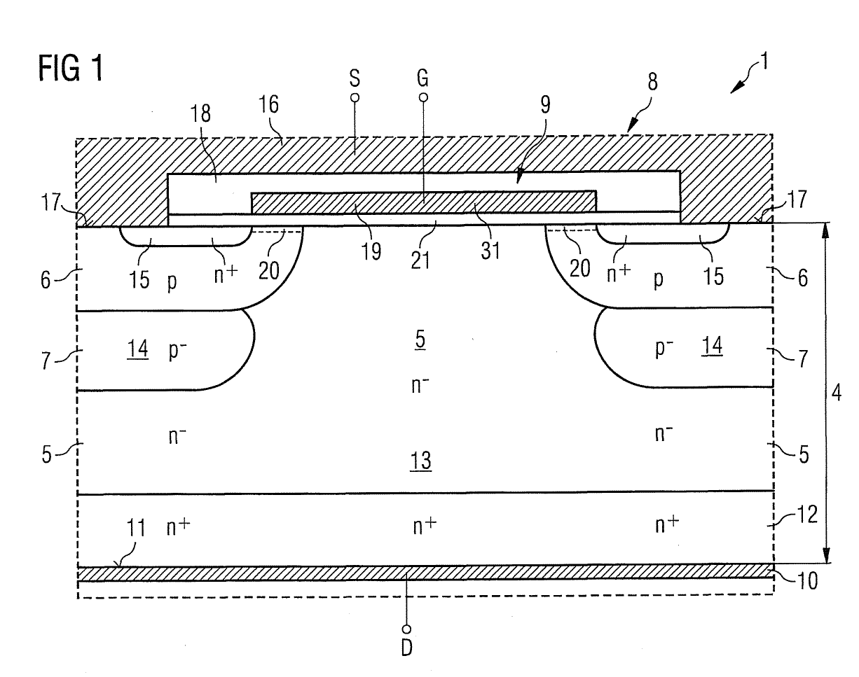

FIG. 1 is a diagrammatic cross-section through a semiconductor device 1, such as an integrated circuit device, according to an embodiment. This semiconductor device 1 with a semiconductor body 4 is a simple DMOS-transistor 8 with a lateral gate structure 9. The gate structure 9 includes an electrically conducting gate electrode 19 located in an oxide layer 18. The gate electrode 19 is electrically connected to a gate terminal G of the semiconductor device 1. The gate electrode 19 is electrically conducting and made of highly doped polysilicon, for example.

Via a gate oxide 21 on the front side 17 of the semiconductor body 4, which is relatively thin compared to the oxide layer 18, the gate electrode 19 influences the DMOS-transistor structure in the semiconductor body 4. This DMOS-transistor structure has a metallic drain electrode 10 on the back side 11 of the semiconductor body 4. The drain electrode 10 is connected to a drain terminal D of the semiconductor device 1. The semiconductor body 4 may have a highly doped n⁺-type semiconductor substrate 12, on which a drift zone material 13 of an n⁻-type drift zone 5 with a significantly lower concentration of doping material is deposited. The n⁻-type drift zone 5 may alternatively be represented by a lightly doped thinned semiconductor substrate with an n⁺-type drain terminal area 12 on its back side.

On the front side 17 of the semiconductor body 4, the semiconductor device 1 includes, in addition to the gate structure 9 with the gate electrode 19 and the gate oxide 21, a source electrode 16 connected to a source terminal of the semiconductor device 1. Near the surface, a highly doped n⁺-type source zone 15 is introduced into the semi-conductor body 4 by ion implantation, by diffusion or by a combination of both. This highly doped n⁺-type source zone 15 is completely surrounded by a complementary p-type body zone 6. The n⁺-p junction is bridged by the electrically conducting source electrode. In this way, the source electrode 19 is electrically connected to the highly doped source zone 15 and the body zone 6.

Together with the n⁻-type drift zone 5, this p-type base zone 6 forms a p-n junction which is flooded by charge carriers in the on state and has a space charge zone in the blocking state. The space charge zone spreads from the p-n⁻ junction between base zone and drift zone towards the n⁺-type substrate and thus towards the drain electrode 10, if the DMOS-transistor 8 is switched from the conductive state to the blocking state. For reverse blocking devices on the other hand, the body zone 6 may be floating.

A gating of the semiconductor device 1 is triggered by the lateral gate structure by applying a control voltage to the gate terminal 6. In this process, a channel region 20 between the highly doped source zone 15 and the lightly doped drift zone 5 is gated. If the control voltage is disconnected from the gate terminal G, the semiconductor device 1 returns to the blocking state. This may generate a reverse current which may reach high values, for example owing to load inductances connected to the semiconductor device 1.

In such a disconnection phase, i.e. in the changeover phase between the conducting and the blocking state of the semiconductor device 1, the device takes up a high blocking voltage even at low currents at the p-n junction between the body zone 6 and the drift zone 5. If semiconductor devices without a field stop zone are exposed to avalanche effects, even low currents can cause the snapping back of the breakdown characteristic, which may result in the destruction of the semiconductor device.

As a preventative measure, the semiconductor device according to FIG. 1 has a field stop zone 7 made of a field stop zone material 14 in the near-surface region below the body zone 6. This field stop zone material 14 has a doping complementary to the drift zone material 13 and a lower concentration of doping material than the body zone 6. As a result, the breakdown characteristic only snaps back at noticeably higher voltages, as the field stop zone only takes up voltage when a blocking current density is exceeded and therefore allows higher voltages without exceeding the critical field strength E_{C} of silicon. This critical field strength E_{C} is determined by approximation by the concentration of doping material within a wide concentration range in accordance with equation (1):

E_{C}=4010·N^{1/8}[V/cm] (1),

wherein N is the concentration of doping material in cm⁻³ in the field region.

At low current densities, the majority of field stop zones are field-free with the exception of their edge regions. At high current densities, however, the field penetrates.

The field stop zone can have a net dose Dₚ of 4·10¹² cm⁻²≦Dₚ≦2·10¹³ cm⁻²; 8·10¹² cm⁻²≦Dₚ≦1·10¹³ cm⁻² in exemplary embodiments. This net dose is above the breakdown charge C_{L} of silicon, which for a larger range of concentration of doping material is determined by approximation by equation (2):

C_{L}=2.67·10¹⁰·N^{1/8}cm⁻² (2),

wherein C_{L} is the breakdown charge of silicon, which is approximately 2·10¹² cm⁻².

Relative to the breakdown charge C_{L}, the field stop zone may have a net dose Dₚ of 1.5·C_{L}≦Dₚ≦10·C_{L}; 3·C_{L}≦Dₚ≦5·C_{L} in exemplary embodiments.

The concentration of doping material Nₚ of the field stop zone may lie between 5·N_{d}≦Nₚ≦100·N_{d} relative to the drift zone doping N_{d} in devices without compensation. This high doping in the p-type field stop zone material 14 relative to the n-type drift zone material 13 can be used to improve conventional DMOS-transistors. In an optimum range, the field stop zone has a concentration of doping material Nₚ relative to the drift zone doping N_{d} of 10·N_{d}≦Nₚ≦50·N_{d}.

A method for the production of a semiconductor device 1 with a semiconductor body 4 and an field stop zone 7 with a doping complementary to a drift zone 5, which is located below a body zone 6 in the semiconductor body 4, includes the following process steps. First, an epitaxial layer 34 of drift zone material 13 is grown in a mono-crystalline manner on, for example, a semiconductor substrate 12. As mentioned above, a substrate material can be used as a drift zone material as an alternative to an epitaxial layer and ground thin towards the end of the process. Following this, a masked ion implantation is carried out from the front side 17 for a structure of the body zone 6 with a doping complementary to the drift zone 5, using a suitable body zone structure mask, such as photoresist, gatepoly or field oxide.

However, this merely creates the body zone 6 and not the field stop zone 7. As the surface area of the field stop zone 7 corresponds to that of the body zone 6 in the present embodiment and method, the body zone mask can be used for the field stop zone 7 as well. A masked high-energy ion implantation for a structure of the field stop zone 7 using the body zone structure mask below the body zone 6 can be carried out before or after the incorporation of the body zone structure. The semiconductor device 1 can then be completed with a source zone 15, a lateral gate structure 9 and a source electrode 16 on the front side 17 and a drain electrode 10 on the back side 11 as well as with device terminals for source S, gate G and drain D. This process offers the advantage that it can be carried out in parallel on a semiconductor wafer as semiconductor substrate for a plurality of semiconductor devices. In the case of planar gates, the structured gatepoly with the associated photoresist mask is used for masking.

Instead of high-energy ion implantation for a structure of the field stop zone 7 below the body zone structure, a doping material diffusing faster than boron, such as the aluminum which may be used for the body zone 6, can be used as a doping material for the field stop zone 7. If boron and the faster diffusing doping material for the field stop zone 7 are applied simultaneously, a greater penetration depth is obtained at the same temperature and time, while the concentration of doping material is reduced to the values specified in the above text.

In a further possible method for doping the field stop zone material 14, a two-stage diffusion and implantation process is used. First, for example, a flat-structured boron implantation for the field stop zone 7 is applied to the front side 17 of the semiconductor body 4. The boron atoms are then diffused deeply into the semiconductor body, while the concentration of doping material is reduced by using a post-diffusion phase. This is followed by a second boron implantation for the base zone 6 with a diffusion mask made of silicon oxide, gatepoly or photoresist. The boron atoms are then driven into the semiconductor body 4 to the depth of the body zone 6 at a lower temperature for a post-diffusion.

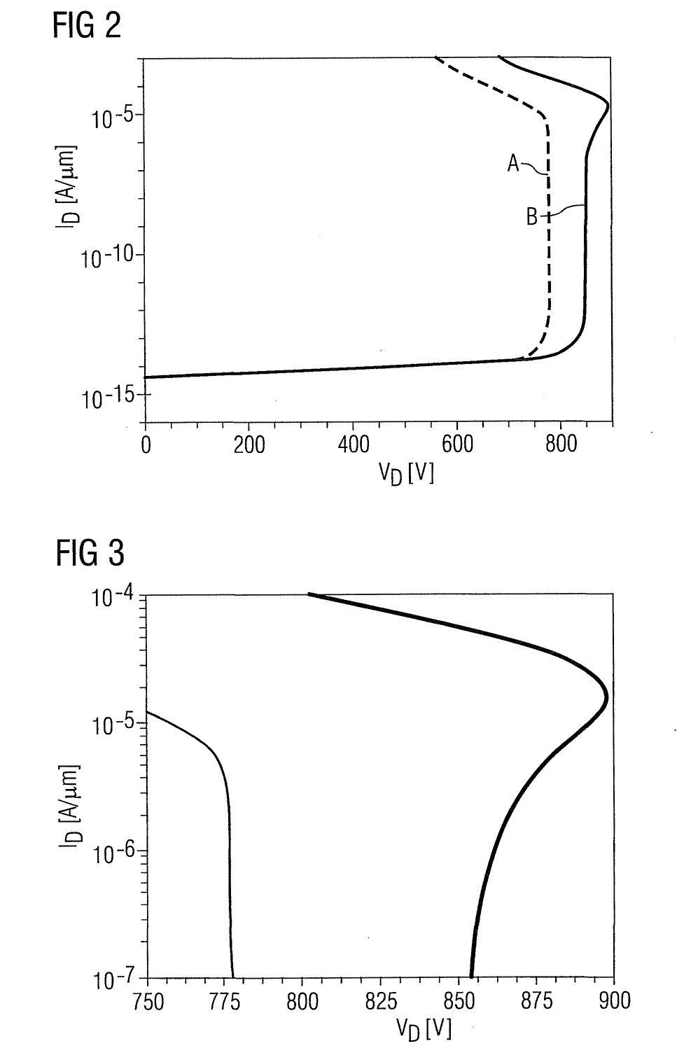

FIG. 2 is a diagram of a numerical device simulation, with curves comparing the breakdown characteristics A and B of semiconductor devices without or with a field stop zone. The drain voltage U_{D} is plotted on the abscissa at intervals of 200 volts. On the ordinate, the drain current is plotted in a logarithmic scale between 10⁻¹⁴ and 10⁻³ in amperes per micrometer (A/μm). The continuous line B relates to the device of this embodiment. In the device with the breakdown characteristic B, a field stop zone of a material with a doping complementary to the drift zone is located near the surface, below the body zone 6 as illustrated in FIG. 1.

Graph A with the dashed line relates to a conventional DMOS-transistor without a field stop zone. As the behaviour of the drain current I_{D} indicates, the breakdown characteristic A of the conventional DMOS-transistor already snaps back at 10⁻⁵ A/μm. If, however, a field stop with a concentration of doping material as specified above is provided, the field stop zone only takes up voltage if a blocking current density is exceeded. The resistance against blocking voltage is therefore more than 100 V higher than in a conventional semiconductor device without this near-surface p-doped field stop zone. In addition, the breakdown characteristic B only snaps back at drain currents I_{D} which exceed those of conventional DMOS-transistors without a field stop zone by at least one order of magnitude. The breakdown voltage of the device B can be adjusted to the value of A. For this purpose, the drift zone has to be shorter than in the device A.

This difference becomes even more pronounced in FIG. 3, which is a diagrammatic representation of an enlarged region of the diagram according to FIG. 2. While the breakdown characteristic of the conventional device without field stop in the upper region of the semiconductor device 1 with a doping complementary to the drain zone snaps back at a few 10⁻⁶ A/μm, this negative snap-back effect occurs only at drain currents above 10⁻⁴ A/μm in a device with a field stop zone according to an embodiment. In addition, the comparison between the drain voltages of A and B illustrates that the field stop zone still takes up voltage if a blocking voltage density is exceeded, so that voltages up to 900 V can be applied without triggering the snap-back effect. This improves the reliability and robustness of the semiconductor device by more than 200 V relative to drain voltage. This advantage can, however, not only be obtained in a DMOS-transistor, but also in other vertically structured semiconductor devices, which are described in greater detail below with reference to the figures.

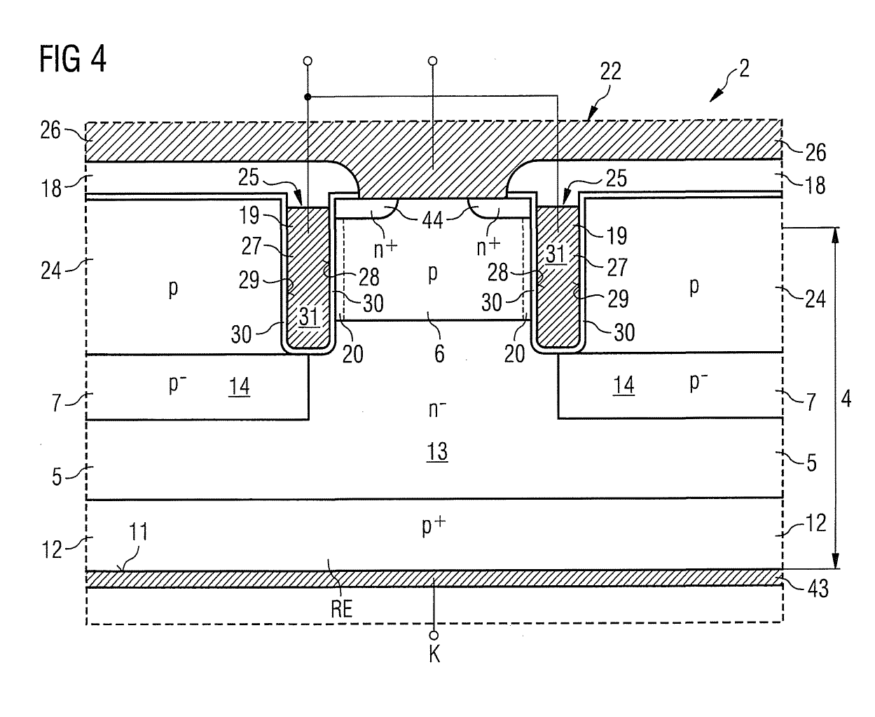

FIG. 4 is a diagrammatic cross-section through another semiconductor device according to an embodiment. This semiconductor device 2 is of the type IGBT 22 (insulated gate bipolar transistor) with a near-surface shielding zone 24 of a complementary conduction type surrounding a cell region 23. A field stop zone 7 is located below the near-surface shielding zone 24 of a complementary conduction type. This field stop zone 7 has a lighter doping than the shielding zone 24.

Within the cell region 23, an IGBT structure with a trench gate structure 25 for the control of the IGBT 22 is implemented. FIG. 4 only illustrates one cell bounded on both sides by trench gate structures 25 in the cell region. These trench gate structures 25 have a trench structure 27 with trench walls 28 and 29, which are in turn covered by a gate oxide layer 30. The trench structure is filled with a gate oxide material 31, which is electrically connected to a gate terminal G. The depth of the trench is selected such that it extends more deeply into the semiconductor body 4 than a body zone 6 located between the two trench structures 27 of the trench gate structures 25 illustrated in FIG. 4. Near the surface, the body zone 6 is surrounded by two emitter zones 44 in ohmic contact with a metallic emitter electrode 26 and electrically connected to an emitter terminal E of the semiconductor device 2.

When a control voltage is applied to a gate terminal G, a vertical channel 20 is gated in the body zone p between the emitter zones 44 and the drift zone 5 below the body zone 6. Now a current can flow from the emitter via the emitter zones 44, the channels 20 and the drift zone 5 towards a back side emitter RE represented by a highly doped p⁺-type zone on the back side 11 of the semiconductor body. The back side 11 of the semiconductor body 4 is metallized for a collector electrode 43 electrically connected to a collector terminal K. It is also possible to locate the collector electrode on the front side of the semiconductor body by using a “drain-up structure,” so that the collector or drain potential adjacent to the cells is drawn from the back side 11 to the front side 17 of the semiconductor body 4 via highly doped regions and there brought into contact with a collector or drain electrode.

The shielding zones 24 surrounding such a cell region 23 extend to the depth of the trench structures 27 for the gate structures 25 or to a slightly greater depth. As an alternative, the shielding zone may only have the depth of the body zone. Below these shielding zones 24, which may have the same or a higher concentration of doping material as (than) the base zone 6 between the trench structures 27, more lightly doped field stop zones 7 with field stop zone material 14 are provided. Although these field stop zones 7 only extend flat near the surface in the region of the shielding zones 24 and do not contact the base zone p between the trench structures 27, they are definitely located below the base zone 6 in a geometrical sense. The remaining drift section of the drift zone 5 between the field stop zone 7 and the highly doped p⁺-type substrate or the back side electrode RE determines the electric strength of the semiconductor device 2, the field stop zones 7 with their doping complementary to the drift zone 5 having the effect explained with reference to FIG. 1 in the de-commutation of the semiconductor component 2.

A method for the production of a semiconductor device 2 as illustrated in FIG. 4, with a semiconductor body 4 and a field stop zone 7 with a doping complementary to the drift zone 5, which is located in the semiconductor body 4 below a shielding zone 24, includes the following process steps. First, an epitaxial layer 34 of drift zone material 13 can be grown on a p⁺-type semiconductor substrate 12. Instead of an epitaxial layer, a substrate with a suitably low concentration of doping material can be used as drift zone material. In this case, the reference number 12 identifies a highly doped implanted p-type region on the back side 11 of the semiconductor body 4. This can be followed by a masked ion implantation for a body zone structure with a doping complementary to the drift zone through a body zone structure mask within a cell region 23.

An intercell structure mask is used for a shielding zone 24 located outside the cell region 23. Through this intercell structure mask, an ion implantation for p-type material can be carried out in the concentration required for the body zone 6. In addition, however, a masked high-energy ion implantation for a structure of a field stop zone 7 below the shielding zone 24 is carried out. The structuring of the shielding zone 24 with the field stop zone 7 and the body zone 6 is followed by an introduction of a trench structure 27 for trench gates within the cell region 23 of the semiconductor body 4. The semiconductor device 2 can then be completed with a trench gate structure 25, emitter zones 44 and emitter electrodes 26, as well as with a collector electrode 43 on the back side 11, which contacts a back side emitter RE.

In addition to the high-blocking IGBT devices and high-voltage diodes illustrated in FIG. 4, the principle of a near-surface p-type field stop 7 can be applied to great advantages in “superjunction DMOS-transistors.” These semiconductor devices have a very even field distribution across the drift zone 5. As a result, the breakdown characteristic of these devices tends to snap back even at very low current densities, as indicated in FIGS. 2 and 3, if there is no provision for a spreading of the space-charge zone in the semiconductor body 4.

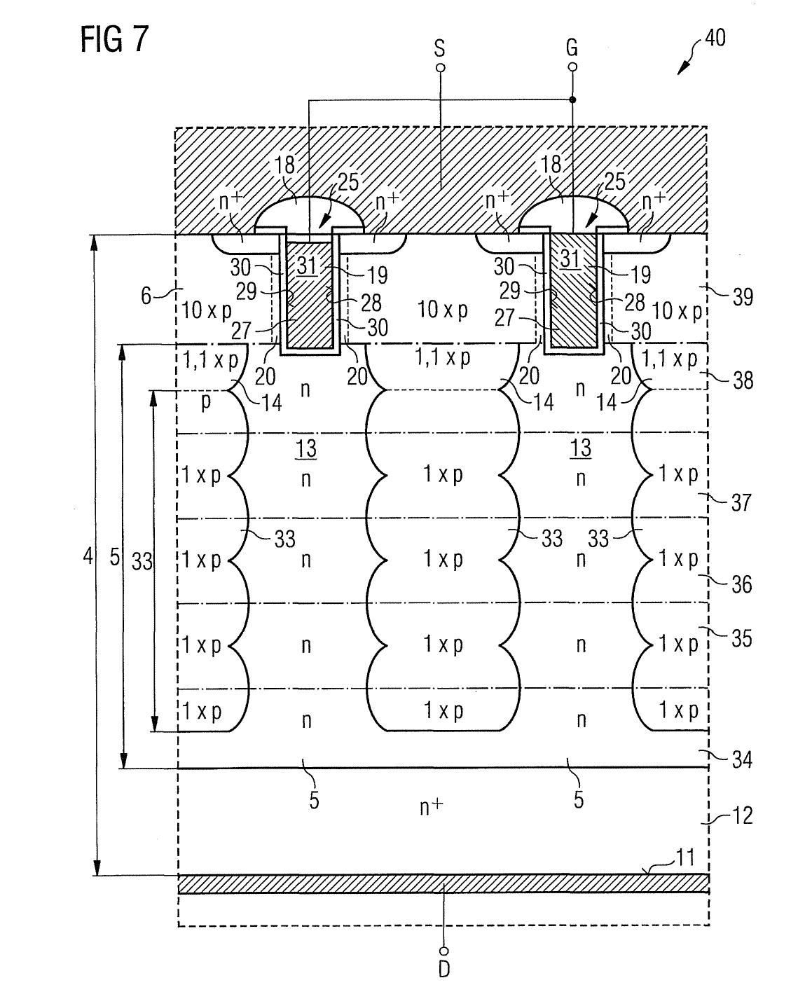

The principle offers the advantage that the required regions of doping material can be incorporated together with others, such as source and body, from the front side 17 of the semiconductor body 4 without the need for multiple epitaxial processes. Such multiple epitaxial processes as illustrated in FIG. 7 are often not available in production facilities for the structuring of semiconductor wafers. In this case, alternative technologies can be useful in the production of diodes and IGBT devices, wherein n-type field stop zones can be introduced in the lower region of the drift zones in a thinned wafer state from the back side of the semiconductor body.

This, however, has the disadvantage that the thin semiconductor chips may break more easily in handling and that the front side can only be metallized in a later process after the diffusion of the n-type field stop from the back side. This proves that the principle disclosed in the present application, i.e. the introduction of a p-type field stop zone below the body zone from the front side of the semiconductor body, offers significant practical benefits.

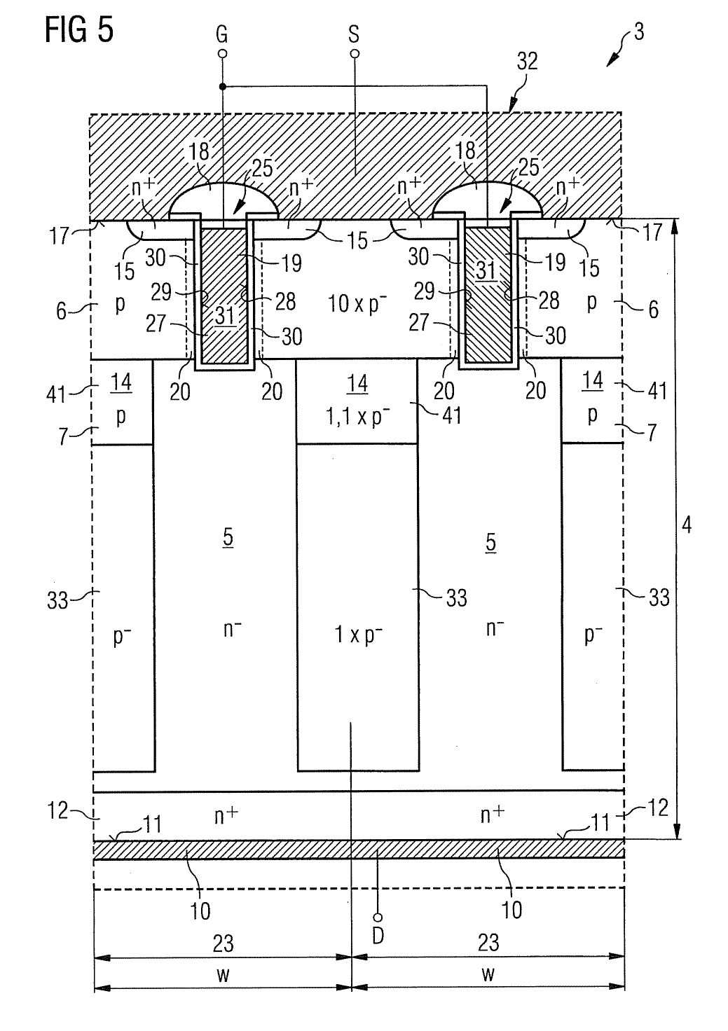

FIG. 5 is a diagrammatic cross-section through a further semiconductor device 3 according to an embodiment. The semiconductor device 3 is a “superjunction DMOS-transistor.” In the region of the drift zones 5, this is provided with vertical, parallel charge compensation zones 33 designed as columns like the drift zone 5 in the illustrated embodiment. As explained in FIG. 4, the gate structure is a trench gate structure 25, which is not explained again in the present context to avoid repetition. Field stop zones 7 of a field stop zone material 14 are located below the body zones 6. The field stop zones 7 contact the body zones 6. The p-type field stop zone material 14 is doped more lightly than the body zone material. The field stop zones 7 extend above the charge compensation zones 33 and are doped more highly than the p-type charge compensation zones 33 located thereunder. While the charge compensation zone 33 is depleted even without any current flow in a blocking situation and has a high electrical field, because the concentration of p-type doping material integrated thereon in a lateral section is >2*CL, the electrical field only penetrates into the field stop zones 7 at high current densities owing to the laterally integrated dose >2*CL.

This drift zone structure with charge compensation zones 33 is placed on a highly doped n⁺-type semiconductor substrate 12. The semiconductor substrate 12 is metallised on the back side 11 of the semiconductor body 4, this metallisation forming a drain electrode 10 in electrical connection with a drain terminal D of the semiconductor device 3. FIG. 5 illustrates two cell regions of a plurality of cell regions of such a semiconductor device 3. The effect of the near-surface p-type field stop zone 7 corresponds to that explained with reference to FIGS. 1, 2 and 3. The charge compensation zones 33 are arranged in a step size w, the field stop zones 7 in the upper regions of the charge compensation zones 33 having a thickness d of d≦0.5·w.

The net doping Dₚ of the field stop zone 7 is, in this embodiment, limited to Nₚ≦5·10¹⁶ cm⁻³ at approximately equal widths of drift zones and field stop zones with charge compensation zones. It is, however, safer to provide the field stop zone with a net doping of Nₚ≦3·10¹⁶ cm⁻³. Relative to the maximum net doping Nₛ of the columns of the drift zones, the net doping Nₚ should be 1.02·Nₛ≦Nₚ≦2·Nₛ. This range is kept as small as possible so that the net doping Dₚ relative to the drift zone doping Dₛ of the columns is 1.05·Nₛ≦Nₚ≦1.5·Nₛ. In addition, the dose of doping material C_{D} in the drift zones 5 or in the charge compensation zones 33, if laterally integrated, should be less than double of the breakdown charge C_{L} with C_{D}>2C_{L} of silicon, with

C_{L}=2.67·10¹⁰N^{1/8}cm⁻² (2).

For strip-shaped field stop regions or for column-shaped field stop regions, the lower limits may be higher by a factor of 2^{1/2} and have the following doses: 2·C_{L}≦Dₚ≦10·C_{L}; 2.02·C_{L}≦Dₚ≦4·C_{L} or 2.05·C_{L}≦Dₚ≦3·C_{L} in exemplary embodiments. The charge compensation zones 33 may be doped homogeneously below the field stop zones 7, and in some embodiments a variable concentration of doping material is provided below the field stop zones 7.

A method for the production of such a semiconductor device 3 with a semiconductor body 4 and with a field stop zone 7 with a doping complementary to the drift section 5, which is located in the semiconductor body 4 below a body zone 6, includes the following process steps. First, an epitaxial layer 34 of drift zone material is grown on an n⁺-type semiconductor substrate 12. Trench structures for charge compensation zones 33 are then incorporated into the epitaxial layer 34.

The trench structures 27 are then filled with a material with a doping complementary to the drift zone 5 for charge compensation zones 33. An upper region 41 is left exposed or initially filled and then etched. This upper region 41 of the trench structure 27 is filled with a material with a doping complementary to the drift section 5 and slightly higher than that for the charge compensation zones 33 to form field stop zones 7. Following this, the semiconductor device 3 can be completed. This method offers the advantage that no additional masks are required for the introduction of the field stop zones 7. On the contrary, the masks used for the charge compensation zones 33 can be used for the upper region 41 with the field stop zones 7.

In the same way, drift zone doping on its own and/or charge compensation zone doping can be introduced via a structure, such as a trench. This can then be filled with a lightly doped semiconductor layer or with a dielectric. The field stop layer can then be diffused or implanted via the walls of the upper trench region by masking the walls of the lower trench region. It is further possible to introduce the doping differential between compensation zones and field stop without masking in the whole device to the specified depth by implantation, diffusion or during the epitaxial process. This slightly compensates the drift zone and slightly increases the forward resistance Rₒₙ. In the multiple epitaxial process, finally, introduction is made simple by implanting a higher dose for a field stop zone at the specified depth while the p-type regions are being implanted.

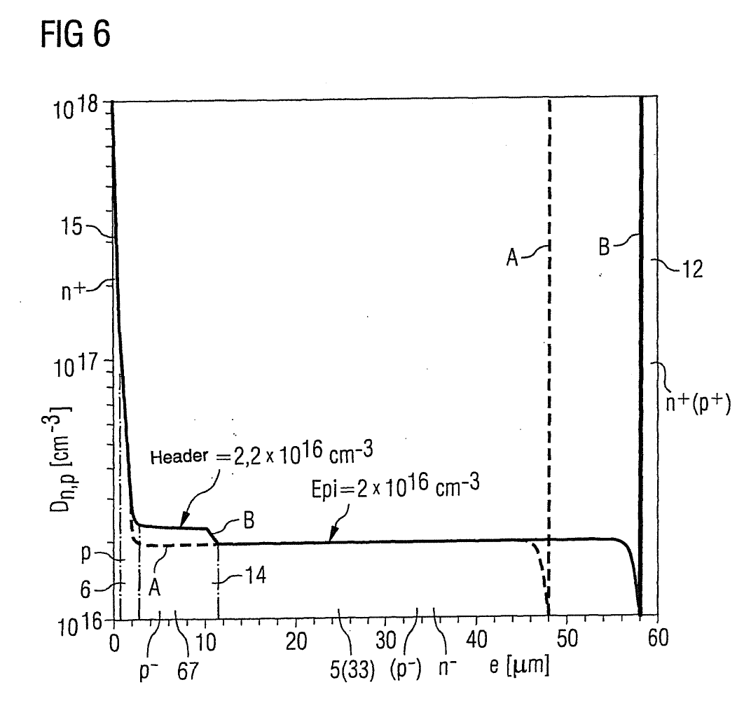

FIG. 6 is a diagrammatic representation of the doping material profiles of semiconductor devices with and without a field stop zone. The doping material profile B for a semiconductor device 3 with a field stop zone is indicated by the dashed line in FIG. 6. The doping material profiles illustrated in FIG. 6 are used, for example, if the drift zone 5 includes additional charge compensation zones 33 as illustrated in FIG. 5 or 7. FIG. 6 illustrates the doping material profiles in a vertical section in a p-type column of a superjunction DMOS-transistor. In a near-surface region, the doping in the p-type column is raised by 10% and reduced by 10% in the region of the n-type column, the n-type column representing a diffusion zone 5, while the p-type column represents a charge compensation zone 33. The length of the drift section has been increased by the thickness of the field stop layer.

On the abscissa, FIG. 6 illustrates the penetration depth e in micrometers in a range of 0, which represents the front side 17 of the semiconductor body, to a depth of 60 μm in the present example. On the ordinate, the concentrations of doping material D_{p,n} per cubic centimetre are plotted in the logarithmic scale in cm⁻³ between 10¹⁴ cm⁻³ and 10¹⁸ cm⁻³. Immediately below the front side 17, at e=0, FIG. 5 illustrates the highly doped n⁺-type source zone 15 with a penetration depth in the submicrometer range.

The body zone 6 reaches a depth up to 2 μm with a doping in the range of 10¹⁶ cm⁻³. In a device without a field stop zone as indicated by the dashed line A, this is adjoined by a lightly doped n⁻-type drift zone 5 made of an epitaxial material, which in the illustrated embodiment has a doping of 2×10¹⁶ cm⁻³ and reaches a penetration depth up to 48 μm. This penetration depth of 48 μm also determines a limit for electric strength, which slightly exceeds 700 volts. This n⁻-type drift zone material is adjoined by a highly doped n⁺-type substrate material 12, so that the impurity profile A greatly exceeds the doping material range illustrated here.

In contrast to such a doping material profile of a conventional DMOS-transistor, the superjunction DMOS-transistor illustrated in FIG. 5 includes a near-surface field stop zone 7 of a p⁻-type material, which in the doping material profile B illustrated in FIG. 6 has a p-type header of 2.2×10¹⁶, so that the concentration of doping material is significantly below the concentration of the body zone 6 and slightly exceeds the basic doping of the epitaxy for the drift section 5. Corresponding to this, the drift zone 5 located below is offset relative to the conventional DMOS-transistor, so that in principle the same resistance against blocking voltage is reached for the semiconductor device equipped with a field stop zone 7. As FIGS. 2 and 3 illustrate, however, the effects on the still tolerable reverse or blocking current if this geometry of the drift zone 5 is exceeded are grave. The breakdown voltage may rise by more than 50 V. For production, a homogeneous layer with a suitably adjusted homogeneous doping can be deposited epitaxially, or a p-type doping homogeneous across the wafer with a height of approximately 10% of the p-type column can be diffused in from above. In the embodiment of the doping material profile B illustrated in FIG. 6, doping is constant across the entire depth.

A doping in the columns which is slightly reduced towards the bottom may be preferable. In this case, for example, trenches can be etched from which p- or n-type columns and/or the field stop zones are diffused out from the surface. The trench structures of the charge compensation zones 33 can be filled with mono-crystalline silicon or with oxide. A further advantage can be achieved if the homogeneous p-doping is carried out with an increase only in the region of the p-type column, because this increases Rₒₙ×A by less than an even, homogeneous p-doping would.

FIG. 7 is a diagrammatic cross-section through a semiconductor device with an epitaxially produced charge compensation zone structure. This semiconductor device 40, too, is a “superjunction DMOS-transistor”, with the difference that the charge compensation zones 33 and the drift zones 5 are represented by column- and strip-shaped regions of epitaxial layers 34 to 39 grown on top of one another. Regions of the second last epitaxial layer 38 are doped as field stop zones 7, with approximately 20% more doping material being introduced into this second last epitaxial layer in the regions of the charge compensation zones 33 than for the remaining doping material zones in the epitaxial layers 34, 35, 36 and 37.

For higher accuracy, the body (base) zones are usually implanted via the front side and then diffused. The p-type doping of the body zone is higher than the doping in the charge compensation zones 33 and higher than in the field stop zones 7. Trench gate structures 25 are incorporated into these base zones 6, so that, if a control voltage is applied to the gate terminal G, vertical channels 20 connect the highly doped source regions 15 to the lightly doped drift zones 5 when the semiconductor device 40 is gated. As an alternative, planar gates may be provided on the semiconductor surface.

A method for the production of such a semiconductor device 40 with a semiconductor body 4 and a field stop zone 7 with a doping complementary to the drift zone 5 and located below a body zone 6 in the semiconductor body 4 includes the following process steps. First, epitaxial layers 34 to 37 of a drift zone material 13 are grown on a semiconductor substrate 12. In this process, column- or strip-shaped doping material zones for charge compensation zones 33 and drift zones 5 are incorporated into each of the epitaxial layers 34 to 37.

This is followed by the growing and doping of a second last epitaxial layer 38 in the region of the charge compensation zones 33 to provide field stop zones 7 with a higher concentration of doping material than in the charge compensation zones 33 and in the drift zones 5. Finally, a last epitaxial layer 39 of body zone material is grown on the existing epitaxial layers 34 to 38 and a trench gate structure 25 is incorporated into this last epitaxial layer. The field stop zone may be introduced into the last epitaxial layer as well. This is then deeply diffused together with the charge compensation zones, before the flat body region is incorporated and diffused in.

Finally, the semiconductor device 40 is completed in the usual further process steps. This method offers the advantage that existing technological processes can be used with suitable mask sets and only the second last or the last mask requires an increased dose for the field stop zones 7 for the implantation or diffusion of the charge compensation zones.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit device with a semiconductor body, comprising;
a drift zone with a first conduction type;
a body zone with a second conduction type complementary to the first conduction type;
a field stop zone;
wherein the field stop zone is located near a surface, has the second complementary conduction type; and
is doped more lightly than the body zone, so that the field stop zone takes up voltage at least if a blocking current density is exceeded.

2. The integrated circuit device of claim 1, wherein the integrated circuit device is a DMOS-transistor with a lateral gate structure and wherein the field stop zone is located below the body zone.

3. The integrated circuit device of claim 1, wherein the integrated circuit device includes a metallic drain electrode on a back side of the semiconductor body, which contacts a highly doped drain terminal region of the semiconductor body.

4. The integrated circuit device of claim 1, wherein a source zone of the first conduction type and doped more highly than the drift zone, which is contacted by a metallic source electrode, is located in the body zone.

5. The integrated circuit device of claim 1, wherein the integrated circuit device is an IGBT with a near-surface shielding zone surrounding a cell region and having a complementary conduction type, and wherein the field stop zone is located below the near-surface, complementary-type shielding zone and is doped more lightly than the complementary-type shielding zone.

6. The integrated circuit device of claim 5, wherein the integrated circuit device includes a metallic back side emitter (RE) in the lower region of the semiconductor body, which is formed by a highly doped semiconductor substrate of the semiconductor body with a doping complementary to a drift zone.

7. The integrated circuit device of claim 5, wherein a trench gate structure is located in a trench and includes a gate oxide layer on the trench walls in a region between the source zone and the drift zone vertically along the body zone.

8. The integrated circuit device of claim 1, wherein the field stop zone has a net doping Nₚ of 4·10¹² cm⁻²≦Dₚ≦2·10¹³ cm⁻².

9. The integrated circuit device of claim 1, wherein the field stop zone has a net doping Nₚ relative to the drift zone doping N_{d} of 5·N_{d}≦Nₚ≦100·N_{d}.

10. The integrated circuit device of claim 1, wherein the field stop zone has a net doping Nₚ relative to the drift zone doping N_{d} of 10·N_{d}≦Nₚ≦50·N_{d}.

11. The integrated circuit device of claim 1, wherein the integrated circuit device is a superjunction device with charge compensation zones with a doping complementary to the drift zone in the drift zone, and wherein the charge compensation zones include near-surface field stop zones between the body zone and the charge compensation zones.

12. The integrated circuit device of claim 1, wherein the charge compensation zones are located in column- or strip-shaped trench structures.

13. The integrated circuit device of claim 11, wherein the charge compensation zones are arranged column-shaped in the drift zone and include the field stop zones in the upper regions.

14. The integrated circuit device of claim 11, wherein the charge compensation zones have a variable concentration of doping material below the field stop zones.

15. The integrated circuit device of claim 11, wherein a trench gate structure is located in a trench and includes on the gate walls a gate oxide layer in a region between the source zone and the drift zones vertically along the body zone.

16. The integrated circuit device of claim 11, wherein the charge compensation zones are arranged in a stop size w and the field stop zone has a thickness d of d≦0.5*w in the upper region of the charge compensation zones.

17. The integrated circuit device of claim 11, wherein the field stop zone has a net doping Nₚ of Nₚ≦5·10¹⁶ cm⁻³.

18. The integrated circuit device according to claim 11, wherein the field stop zone has a net doping Nₚ of Nₚ≦3·10¹⁶ cm⁻³.

19. The integrated circuit device of claim 11, wherein the field stop zone has a net doping Nₚ relative to the drift zone doping Nₛ of the columns of 1.02·Nₛ≦Nₚ≦2·Nₛ.

20. The integrated circuit device of claim 11, wherein the field stop zone has a net doping Nₚ relative to the drift zone doping Nₛ of the columns of 1.05·Nₛ≦Nₚ≦1.5·Nₛ.

21. The semiconductor component of claim 1, wherein the field stop zones include high-energy implanted doping materials below the body zones or below regions of a complementary conduction type.

22. A method for the production of an integrated circuit device, comprising:
performing a masked ion implantation on a semiconductor body for a body zone structure with a doping complementary to a drift zone through a body zone structure mask;
performing masked high-energy ion implantation for a field stop zone structure through the body zone structure mask below the body zone; and
completion of the integrated circuit device.

23. A method for the production of an integrated circuit device, comprising:
performing a masked ion implantation on a semiconductor body for a body zone structure with a doping complementary to a drift zone through a body zone structure mask within a cell region and for a shielding zone through an intercell structure mask;
performing a masked high-energy ion implantation for a field stop zone structure through the intercell structure mask,
incorporating a trench structure for trench gates within the cell region; and
completion of the integrated circuit device.

24. A method for the production of an integrated circuit device, comprising:
incorporating a trench structure for charge compensation zones into an epitaxial layer;
filling the trench structure with a material with a doping complementary to a drift zone for charge compensation zones;
filling an upper region of the trench structure with a material with a doping complementary to the drift section and higher than that for the charge compensation zones to provide field stop zones; and
completion of the integrated circuit device.

25. A method for the production of an integrated circuit device, comprising:
with a semiconductor body and a field stop zone with a doping complementary to the drift zone and located below a body zone, the method comprising:
growing epitaxial layers of drift zone material on a semiconductor substrate accompanied by the incorporation of column- or strip-shaped doping material zones for charge compensation zones into each of the epitaxial layers;
growing and doping a second epitaxial layer in the region of the charge compensation zones to provide field stop zones with a higher concentration of doping material than the charge compensation zones; and
completion of the integrated circuit device.
